(19) United States
(12) Patent Application Publication
(10) Pub. No.: US 2020/0150159 A1
(43) Pub. Date: May 14, 2020

(54) ANOMALY DETECTION DEVICE, ANOMALY DETECTION METHOD, AND STORAGE MEDIUM

(71) Applicants: Kabushiki Kaisha Toshiba, Minato-ku (JP); Toshiba Digital Solutions Corporation, Kawasaki-shi (JP)

(72) Inventors: Yuki Takeda, Kawasaki-shi (JP); Kentaro Takeda, Kawasaki-shi (JP)

(73) Assignees: Kabushiki Kaisha Toshiba, Minato-ku (JP); Toshiba Digital Solutions Corporation, Kawasaki-shi (JP)

(21) Appl. No.: 16/706,922

(22) Filed: Dec. 9, 2019

Related U.S. Application Data
(63) Continuation of application No. PCT/JP2018/022730, filed on Jun. 14, 2018.

(30) Foreign Application Priority Data
Jun. 14, 2017 (JP) 2017-116610

(51) Int. Cl. G01R 19/165; G01R 19/25; G01R 19/30; G06N 20/00

(52) U.S. Cl. CPC G01R 19/16528; G06N 20/00; G01R 19/30; G01R 19/2506

(57) ABSTRACT

The anomaly detection device according to an embodiment has a calculator and a determiner. The calculator is configured to calculate a degree of anomaly according to a predictive value that is predicted through machine learning using data acquired from a target device and a measurement value that is actually measured for the target device. The determiner is configured to determine whether a change of the degree of anomaly indicates an anomaly of the target device according to a degree of a change of the degree of anomaly calculated by the calculator within a predetermined time range.

### CROSS-REFERENCE TO RELATED APPLICATION

This application is based upon and claims the benefit of priority from Japanese Patent Application No. 2017-116610, filed on Jun. 14, 2017 and PCT/JP2018/022730 filed on Jun. 14, 2018; the entire contents of which are incorporated herein by reference.

### FIELD

An embodiment of the present invention relates to an anomaly detection device, an anomaly detection method, and a storage medium.

### BACKGROUND

Anomaly detection techniques using machine learning have become known in recent years. For example, a technique of detecting anomalies of an apparatus by calculating the error between a predictive value that is predicted through machine learning with data acquired from the apparatus to be monitored and a measurement value that is actually measured and comparing the error with a preset threshold is known.

A threshold used in a conventional anomaly detection technique is set in advance by a designer according to past measurement values and the like. There are cases in which, if a high threshold is set, apparatus failure or the like would have already progressed when an error exceeds the threshold. For this reason, it is necessary to set a low threshold so that an anomaly can be detected due to an error at a stage at which apparatus failure or the like has not progressed (e.g., a stage at which no sign of failure is shown). However, if a low threshold is set, there may be cases of “false detection” in which a state that is not supposed to be determined as an anomaly is determined as an anomaly happening frequently.

There are diverse causes of the above-described false detection. That is, since false detection is determined according to the intention of a designer that “a state that meets a condition should not be treated as an anomaly,” there are cases in which it is not desirable for a temporary fluctuation of a value or the like to be determined as an anomaly. In addition, when all states of a system are not learned in machine learning, a fluctuation of a value within a normal range resulting from a change in a state may be mistakenly determined as an anomaly. For example, a case where an operation at the time of “heating” is evaluated using a model learned from data at the time of “cooling,” a case where, when conditions for a test operation and an actual operation are different, an actual operation is evaluated using a model learned from data of the test operation, and the like are conceivable. Thus, a technique that can reduce false detection while anomaly detection can be performed with a high accuracy is required.

### BRIEF DESCRIPTION OF THE DRAWINGS

FIG. 1 is a view showing an example of an anomaly detection device according to an embodiment.

FIG. 2 is a view showing patterns showing trends of increasing degrees of anomalies.

FIG. 3 is a flowchart showing an example of a process of the anomaly detection device according to the embodiment.

FIG. 4 shows graphs showing a temporal change of a degree of anomaly before and after filtering according to the embodiment.

FIG. 5 shows graphs showing a temporal change of a degree of anomaly before and after filtering according to the embodiment.

FIG. 6 is a flowchart showing an example of an anomaly determination process of the anomaly detection device according to the embodiment.

FIG. 7 shows a view showing the states before and after time series data corresponding to pattern 1 was filtered in Example 1.

FIG. 8 shows a view showing the states before and after time series data corresponding to pattern 2 was filtered in Example 1.

FIG. 9 shows a view showing the states before and after time series data corresponding to pattern 3 was filtered in Example 1.

FIG. 10 shows a view showing the states before and after time series data corresponding to pattern 4 was filtered in Example 1.

FIG. 11 shows a view showing changes in a degree of anomaly when time series data of the degree of anomaly was filtered and measurement values used for calculating the degree of anomaly determined to be rectangular were learned in Example 2.

### DETAILED DESCRIPTION

An object of the present invention is to provide an anomaly detection device, an anomaly detection method, and a storage medium that enable false detection in anomaly detection to be reduced and accuracy in detection to be enhanced.

An anomaly detection device according to an embodiment has a calculator and a determiner. The anomaly detection device according to an embodiment has a calculator and a determiner. The calculator is configured to calculate a degree of anomaly according to a predictive value that is predicted through machine learning using data acquired from a target device and a measurement value that is actually measured for the target device. The determiner is configured to determine whether a change of the degree of anomaly indicates an anomaly of the target device according to a degree of a change of the degree of anomaly calculated by the calculator within a predetermined time range.

An anomaly detection device, an anomaly detection method, and a storage medium according to embodiments of the present invention will be described below with reference to the drawings.

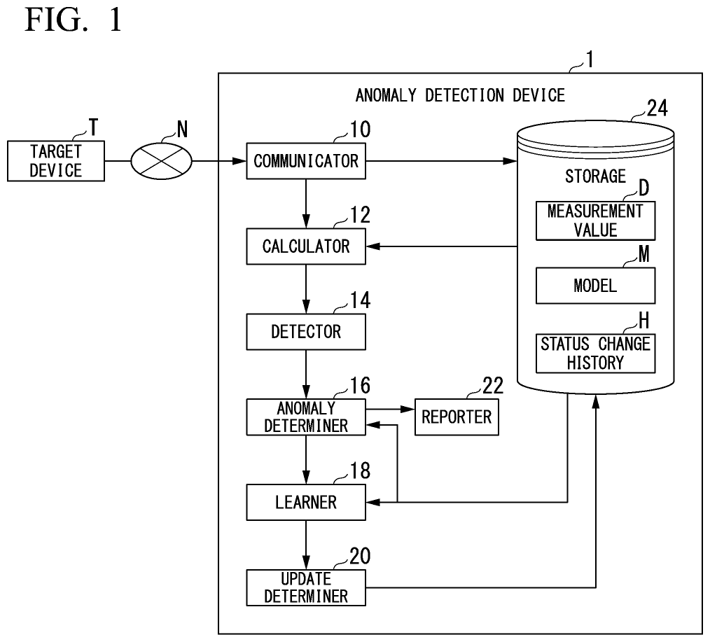

FIG. 1 is a view showing an example of an anomaly detection device 1 according to an embodiment. The anomaly detection device 1 detects the occurrence of an anomaly of a target device T, which is a target for anomaly detection, using machine learning. The anomaly detection device 1 acquires data (measurement values and the like) from the target device T, calculates a degree of anomaly according to a predictive value of a behavior of the target device T that is predicted from the data and a measurement value that is actually measured, and detects the occurrence of an anomaly of the target device T according to a degree of change of the degree of anomaly (e.g., an uptrend or a downtrend of the degree of anomaly). A degree of anomaly refers to an index value indicating a degree of difference (a degree of divergence) between a predictive value and a measurement value of the target device T.

The anomaly detection device 1 calculates, for example, the error between a predictive value and a measurement value of the target device T at some point in the future, or the error between a predictive value and a measurement value of the target device T at a current point (at the time of data acquisition) as a degree of anomaly. The anomaly detection device 1 calculates a degree of anomaly using, for example, a square error. Further, the anomaly detection device 1 may calculate a degree of anomaly using another arbitrary error calculation method such as an absolute error or the like. In addition, a calculation method for a degree of anomaly is not limited to one according to the error between a predictive value and a measurement value of the target device T, and an arbitrary method may be used as long as a degree of anomaly indicates an index value indicating a degree of difference between the predictive value and the measurement value of the target device T. In addition, the degree of anomaly may be 0 or a positive value and may be defined to indicate that the error between a predictive value and a measurement value of the target device T becomes greater as the value increases (as the absolute value increases). Alternatively, the degree of anomaly may be 0 or a negative value and may be defined to indicate that the error between a predictive value and a measurement value of the target device T becomes greater as the value decreases (the absolute value increases). An example in which the degree of anomaly is 0 or a positive value and is defined to indicate that the error between a predictive value and a measurement value of the target device T becomes greater as the value increases will be described below. Further, detection of an anomaly in the present embodiment includes both detection of a sign of failure of the target device T and detection of failure of the target device T. An example in which detection of an anomaly is detection of a sign of failure will be described below.

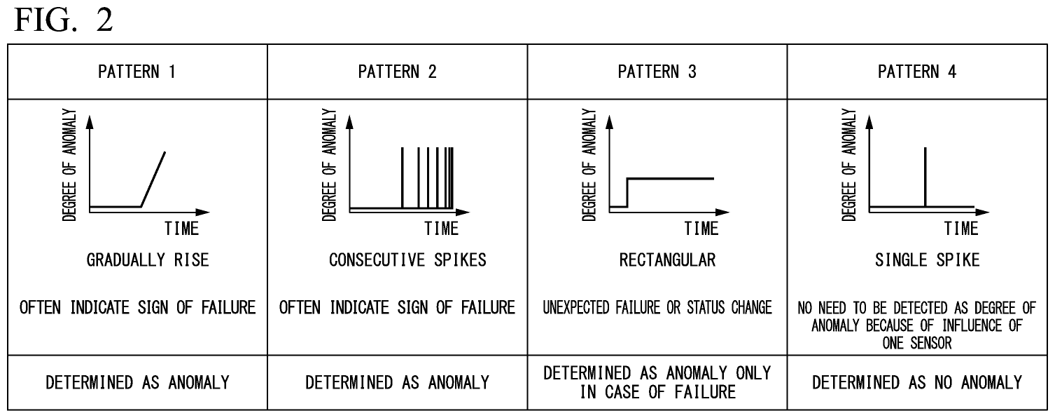

Uptrends of degrees of anomaly that are targets of the present embodiment may be classified into, for example, four patterns as shown in FIG. 2. Pattern 1 shows an uptrend in which a degree of anomaly gradually rises with the passage of time. Pattern 2 shows an uptrend in which there are consecutive spike-shaped rises in degree of anomaly. Since the uptrends of Patterns 1 and 2 are often determined to be signs of failure, the anomaly detection device 1 determines an uptrend in the degree of anomaly corresponding to any of these patterns as an “anomaly.”

Pattern 3 shows an uptrend in which a degree of anomaly suddenly rises and then becomes stable (a degree of anomaly with respect to time is plotted as a rectangle). The uptrend of Pattern 3 is assumed to indicate that unexpected failure has occurred (i.e., an anomaly has occurred) as indicated by the sudden rise of the degree of anomaly or a state of the target device T has changed (i.e., no anomaly has occurred). A change in a state of the target device T refers to a change in an operation state, an operation environment or the like of the target device T. For example, the change indicates that, if the target device T is an air-conditioning apparatus, an operation has been changed from “cooling” to “heating,” and if the target device T is a production facility, products have been changed, or the like. In such a case, the anomaly detection device 1 determines that “there is an anomaly” only when it is determined that unexpected failure has occurred, and determines that “there is no anomaly (false detection)” when it is determined that the state of the target device T has been changed.

Pattern 4 shows an uptrend in which there is a single spike-shaped rise in degree of anomaly. The uptrend of Pattern 4 is assumed to be a case where, for example, only one sensor outputs a peculiar value (a measurement value significantly different from a predictive value). In this case, the anomaly detection device 1 determines an uptrend in a degree of anomaly corresponding to Pattern 4 to be “false detection.”

The target device T includes, for example, an apparatus, a device, a facility, a factory, a plant, and the like that can output arbitrary measurement values. The anomaly detection device 1 and the target device T are connected to each other via a network N. The network N includes, for example, a wide area network (WAN), a local area network (LAN), the Internet, a leased line, and the like.

The anomaly detection device 1 has, for example, a communicator 10, a calculator 12, a detector 14, an anomaly determiner 16 (an example of a determiner), a learner 18, an update determiner 20 (an example of a decider), a reporter 22, and a storage 24. The anomaly detection device 1 acquires data from the target device T via the communicator 10 and causes the data to be stored in the storage 24. The data acquired from the target device T includes a measurement value D measured by a sensor or the like installed in the target device T, a status change history H indicating a history of a status change of the target device T, operation conditions, and the like.

The calculator 12 calculates a degree of anomaly using the measurement value D input from the communicator 10. For example, the calculator 12 reads, from the storage 24, a model M (a first model) generated by learning an operation of the target device T, calculates a predictive value of a behavior of the target device T through machine learning using the model M, and then calculates a degree of anomaly which is the error between the predictive value and the measurement value.

Deep learning technology using a deep neural network (DNN), a convolutional neural network (CNN), a recurrent neural network (RNN), or the like may be applied to the machine learning by the calculator 12.

The detector 14 performs filtering on the degree of anomaly calculated by the calculator 12 and detects the presence of a degree of anomaly in the data of the filtered degree of anomaly, the degree of anomaly exceeding a preset threshold or being equal to or greater than the threshold (which will be simply referred to as a “degree of anomaly exceeding the threshold” below). That is, the detector 14 reduces a degree of anomaly which has a degree of change with respect to time that is equal to or greater than a predetermined value. Accordingly, the detector 14 smooths the change of the degree of anomaly in the time direction. The detector 14 performs filtering using, for example, a low-pass filter (LPF). The detector 14 performs filtering in which, for example, only data of a change of a degree of anomaly with respect to time having a value equal to or smaller than a predetermined frequency is allowed to pass. Further, the detector 14 may detect the presence of a degree of anomaly in the data of the degree of anomaly calculated by the calculator 12, the degree of anomaly exceeding the preset threshold or being equal to or greater than the threshold (a rise of the degree of anomaly), without performing the above-described filtering. An example in which the detector 14 performs the above-described filtering will be described below.

The anomaly determiner 16 determines whether a degree of anomaly exceeding the threshold indicates an “anomaly (a sign of failure)” or “not an anomaly (false detection).” That is, the anomaly determiner 16 determines whether a rise of the degree of anomaly indicates an anomaly of the target device T according to the degree of change of the rise of the degree of anomaly calculated by the calculator 12 within a predetermined time range. The anomaly determiner 16 determines “anomaly” or “false detection” according to whether data indicating an uptrend in the degree of anomaly exceeding the threshold corresponds to a rule for ignoring a preset degree of anomaly (determination condition), whether the rise of the degree of anomaly is stable within the predetermined determination target time (falls within the predetermined range), and whether a status of the target device T has changed. Details of the anomaly determiner 16 will be described below.

The learner 18 performs re-learning using learning data including a measurement value after a status change of the target device T and generates a new model (a second model) when the anomaly determiner 16 determines that a status of the target device T has changed. The learner 18 generates the new model by, for example, performing re-learning using data in which the data used to generate the current model (the first model) is randomly mixed with the measurement values after the status change of the target device T.

The update determiner 20 performs accuracy evaluation on the current model and the new model. The update determiner 20 compares the degree of anomaly calculated from the predictive value predicted using the current model (a first degree of anomaly) with a degree of anomaly calculated from a predictive value predicted using the new model (a second degree of anomaly), and determines the model used for calculating the lower degree of anomaly to be a model with higher accuracy. When the current model is determined to have higher accuracy, the update determiner 20 determines the current model as a model to be used for subsequent machine learning, and the model (the current model) stored in the storage 24 is not updated. On the other hand, when the new model is determined to have higher accuracy, the update determiner 20 determines the new model as a model to be used for subsequent machine learning, and the model (the current model) stored in the storage 24 is updated to the new model.

The reporter 22 reports to a manager and the like that an anomaly has occurred when the anomaly determiner 16 determines an “anomaly.” The reporter 22 reports that an anomaly has occurred using a voice, an alarm sound, or the like. Further, the reporter 22 may display that an anomaly has occurred on a display (not shown).

Each of the functional units of the anomaly detection device 1 is implemented by a processor such as a CPU mounted in a computer or the like executing a program stored in a program memory or the like. Further, the functional units may be implemented by hardware such as a large scale integration (LSI), an application specific integrated circuit (ASIC), a field-programmable gate array (FPGA), or a graphics processing unit (GPU) having a similar function to the program execution of a processor, or implemented by collaboration of software and hardware.

The storage 24 stores the measurement value D acquired from the target device T, the model M, the status change history, and the like. The storage 24 is realized by, for example, a random access memory (RAM), a read only memory (ROM), a hard disk drive (HDD), a flash memory, an SD card, a register, a hybrid storage device obtained by combining a plurality of the above-described devices, or the like. In addition, a part of or the entire storage 24 may be an external device that the anomaly detection device 1 can access, such as a network attached storage (NAS) or an external storage server.

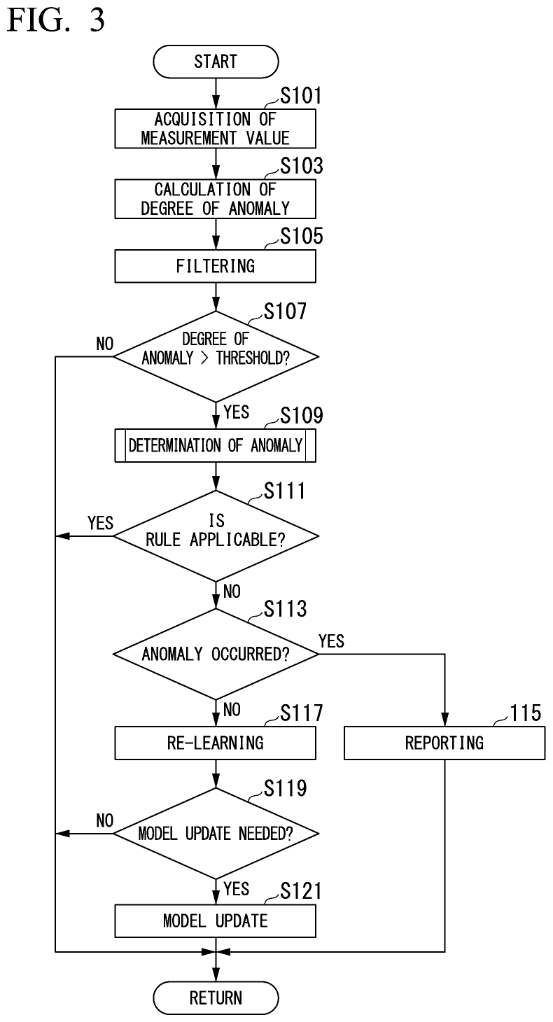

Next, an operation of the anomaly detection device 1 will be described. FIG. 3 is a flowchart showing an example of a process of the anomaly detection device 1. The process of the flowchart shown in FIG. 3 is continuously repeated while anomaly detection for the target device T is performed.

First, the anomaly detection device 1 acquires a measurement value D from the target device T via the communicator 10 (Step S101). The anomaly detection device 1 causes the acquired measurement value D to be stored in the storage 24. When a status of the target device T has changed, the anomaly detection device 1 acquires a status change history H indicating a history of the status change and causes the status change history to be stored in the storage 24.

Next, the calculator 12 calculates a degree of anomaly using the measurement value D input from the communicator 10 (Step S103). For example, the calculator 12 reads a model M from the storage 24, calculates a predictive value of a behavior of the target device T through machine learning using the model M, and calculates a degree of anomaly which is the error between the predictive value and the measurement value. The calculator 12 calculates, for example, a predictive value of a behavior of the target device T at some point in the future, and calculates a degree of anomaly which is the error between the predictive value and the measurement value that is actually measured at the same time point. The calculator 12 inputs the calculated degree of anomaly to the detector 14.

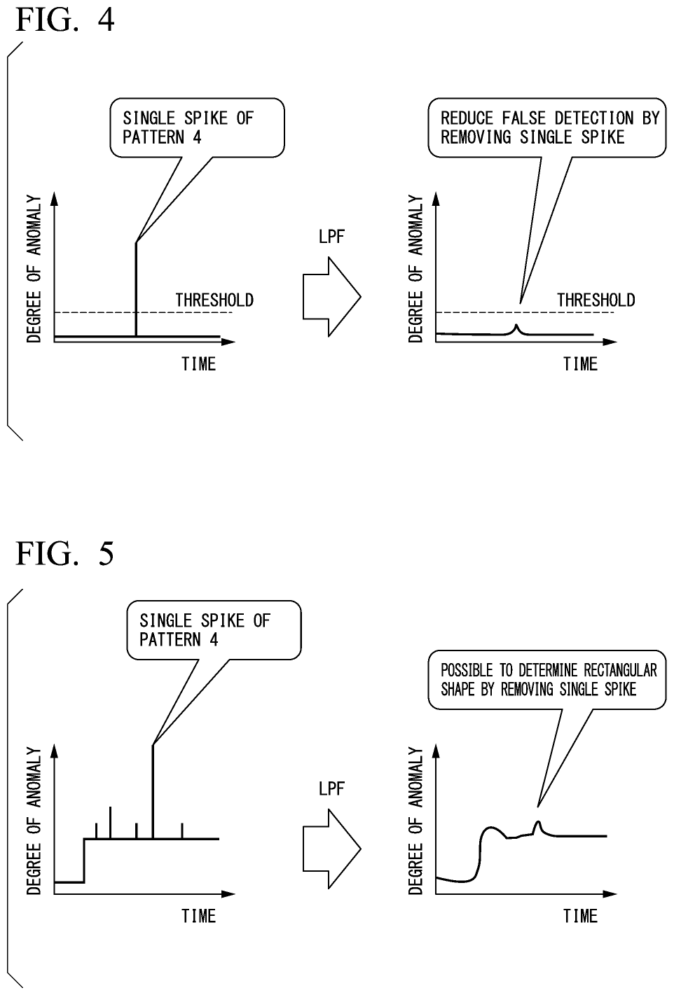

Next, the detector 14 performs filtering on the degree of anomaly input from the calculator 12 (Step S105). The detector 14 performs filtering using, for example, a low-pass filter. FIGS. 4 and 5 show graphs showing temporal changes of the degree of anomaly before and after the filtering. As shown in FIG. 4, the rise of the single spike-shaped degree of anomaly corresponding to “Pattern 4” shown in FIG. 2 is reduced by the filtering. Accordingly, in a process of the anomaly determiner 16, which will be described below, the single spike-shaped rise of the degree of anomaly is not determined as an “anomaly,” and thus false detection can be reduced.

In addition, as shown in FIG. 5, by reducing the rise of the single spike-shaped degree of anomaly corresponding to “Pattern 4” shown in FIG. 2 by filtering, a rectangular uptrend in a degree of anomaly corresponding to “Pattern 3” shown in FIG. 2 can be determined. Accordingly, in the process of the anomaly determiner 16 which will be described below, stability of the degree of anomaly can be determined sooner, an uptrend in the degree of anomaly becomes easy to ascertain, and the rectangle corresponding to “Pattern 3” shown in FIG. 2 can be determined. Further, the detector 14 may use another filter that is likely to make it easier to catch the uptrend in the degree of anomaly, instead of a low-pass filter. In addition, the detector 14 may exclude data of a degree of anomaly that conforms to a predetermined rule for an uptrend in the degree of anomaly (e.g., a rule for the number of spike-shaped rises of degree of anomaly, the frequency of appearance thereof, or the like) according to the rule.

Next, the detector 14 determines whether there is data exceeding the threshold in the data of the filtered degree of anomaly (Step S107). When the detector 14 determines that there is no data exceeding the threshold in the data of the filtered degree of anomaly, the anomaly detection device 1 returns to the above-described measurement value acquisition process and repeats the similar process, without performing the subsequence processes of the present flowchart.

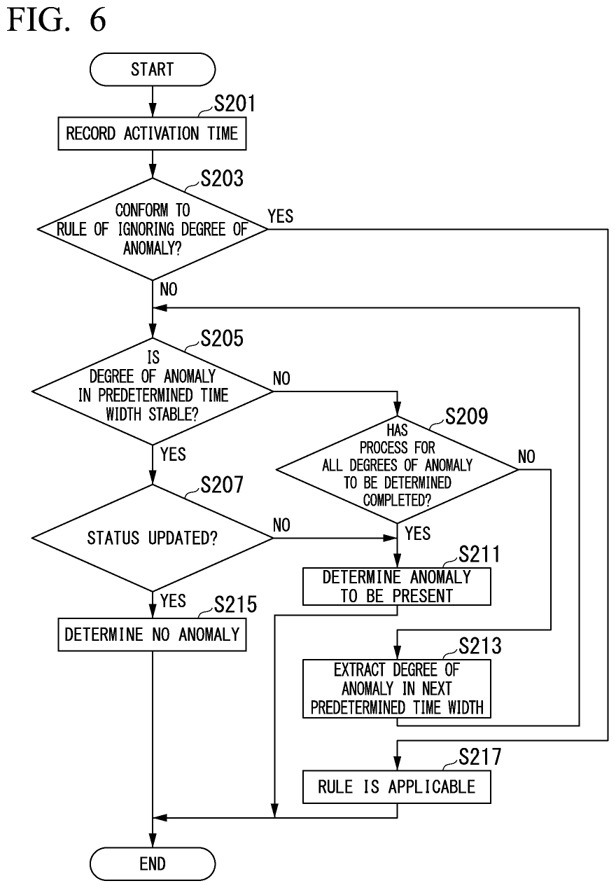

On the other hand, when the detector 14 determines that there is data exceeding the threshold in the data of the filtered degree of anomaly, the anomaly determiner 16 is activated. The anomaly determiner 16 activated by the detector 14 performs anomaly determination for determining whether the degree of anomaly exceeding the threshold is an “anomaly” or “false detection” (Step S109). FIG. 6 is a flowchart showing an example of an anomaly determination process of the anomaly detection device 1.

First, the anomaly determiner 16 records an activation time t at which the anomaly determiner is activated by the detector 14 in, for example, a memory (not shown), the storage 24, or the like (Step S201). Next, the anomaly determiner 16 determines whether the measurement value used in the calculation of the degree of anomaly exceeding the threshold conforms to a rule for ignoring the degree of anomaly (Step S203). For example, when “an output voltage is 0 volts (excluding anomaly detection targets due to a suspension period)” is set in advance as a rule for ignoring a degree of anomaly and a measurement value corresponds to this rule, the anomaly determiner 16 determines that the measurement value conforms to the rule for ignoring the degree of anomaly. When the anomaly determiner 16 determines that the measurement value used for calculating the degree of anomaly exceeding the threshold conforms to the rule for ignoring the degree of anomaly, the anomaly determiner determines “the rule is applicable” (Step S217) and finishes the process of the present flowchart.

On the other hand, when the anomaly determiner 16 determines that the measurement value used for calculating the degree of anomaly exceeding the threshold does not conform to the rule for ignoring the degree of anomaly, the anomaly determiner 16 extracts a degree of anomaly included in a predetermined time width X from the activation time t, and determines whether the degree of anomaly in the time width X is stable (Step S205). The anomaly determiner 16 determines, for example, whether the standard deviation of the extracted degree of anomaly in the time width X is lower than or equal to a predetermined variation threshold D, and determines that the degree of anomaly is stable when the standard deviation is lower than or equal to the predetermined variation threshold D. The anomaly determiner 16 determines a rectangular uptrend in the degree of anomaly similar to Pattern 3 shown in FIG. 2 as a stable degree of anomaly with the passage of time.

When the anomaly determiner 16 determines that the degree of anomaly in the time width X is stable, for example, the anomaly determiner 16 refers to the status change history H stored in the storage 24 and determines whether a status of the target device T has changed from a time (t-A) obtained by subtracting a time A required for a status change from the activation time t to the activation time t (Step S207). When a status of the target device T has changed, it is assumed that the rise of the degree of anomaly has been caused by the status change. Thus, when a status of the target device T is determined to have changed, the anomaly determiner 16 determines “no anomaly” (Step S215) and finishes the process of the present flowchart. On the other hand, when a status of the target device T has not changed, it is assumed that the rise of the degree of anomaly has been caused by any anomaly, rather than by a status change. Thus, when a status of the target device T is determined not to have changed, the anomaly determiner 16 determines “anomaly is present” (Step S211) and finishes the process of the present flowchart.

Meanwhile, when the anomaly determiner 16 determines that the degree of anomaly in the time width X is not stable, the anomaly determiner determines whether processes for all the degrees of anomaly to be determined have been completed (Step S209). For example, when the degree of anomaly included in the period from the activation time t to the time that reached after a predetermined time S elapses is set to be determined, the anomaly determiner 16 determines whether the process for the degrees of anomaly included in the period from the activation time t to the time reached after the predetermined time S elapses has been completed. When the anomaly determiner 16 determines that the processes for all the degrees of anomaly to be determined have been completed (when the degree of anomaly is not stable in the period from the activation time t to the time reached after the predetermined time S elapses), the anomaly determiner determines “anomaly is present” (Step S211), and finishes the process of the present flowchart. On the other hand, when the anomaly determiner 16 determines that the processes for all the degrees of anomaly to be determined have not been completed, the anomaly determiner extracts a degree of anomaly in the next time width X (i.e., a degree of anomaly included in the period from the activation time t+X to t+2X) (Step S213), and determines whether the degree of anomaly in the next time width X is stable (Step S205).

Description will return to the flowchart shown in FIG. 3. Next, when the anomaly determiner 16 determines “the rule is applicable,” (Step S111), the anomaly determiner does not perform the subsequent processes of the present flowchart, returns to the above-described measurement value acquisition process again, and repeats the same processes.

On the other hand, when the anomaly determiner 16 does not determine “the rule is applicable” but determines “an anomaly is present” (Step S113), the reporter 22 is activated. The reporter 22 reports that an anomaly has occurred to the manager or the like (Step S115).

On the other hand, when the anomaly determiner 16 does not determine “the rule is applicable” but determines “no anomaly” (Step S113) (i.e., when a status of the target device T is determined to have changed), the learner 18 is activated. The learner 18 performs re-learning using learning data including measurement values after the status change of the target device T (Step S117) and generates a new model. The learner 18, for example, performs re-learning using data obtained by randomly mixing the data used for generating the current model and the measurement values after the status change of the target device T and generates a new model. The learner 18 inputs the generated new model, the learning data used in the re-learning, and evaluation data obtained by excluding the learning data used in the re-learning from measurement values for a latest predetermined period (e.g., the last one month, etc.) to the update determiner 20. Next, the update determiner 20 evaluates the accuracy of the current model and the new model using the evaluation data input from the learner 18 and determines whether a model update is needed (Step S119). The update determiner 20 compares, for example, a degree of anomaly calculated from a predictive value predicted using the current model with a degree of anomaly calculated from a predictive value predicted using the new model, determines that model update is needed when the degree of anomaly according to the current model is higher than the degree of anomaly according to the new model, and determines that model update is not needed when the degree of anomaly according to the current model is lower than the degree of anomaly according to the new model. The update determiner 20 determines which model has a lower degree of anomaly using the average of degrees of anomaly or the like calculated from a plurality of pieces of data included in the evaluation data.

When the update determiner 20 determines that a model update is needed, the update determiner updates the current model stored in the storage 24 to the new model (Step S121). On the other hand, when the update determiner 20 determines that a model update is not needed, the update determiner does not update the current model stored in the storage 24. Thereby, the series of processes of the present flowchart are finished, the process returns to the above-described measurement value acquisition process again, and the same processes are repeated.

The embodiment will be described more specifically using the examples below.

### Example 1

In Example 1, time series data of a degree of anomaly was provided, and the results obtained by performing filtering on the time series data of a degree of anomaly using a low-pass filter are shown. The sampling frequency for the filtering was set to 1.0 (Hz), the number of taps was set to 600, and the cutoff frequency was set to 0.05 (Hz).

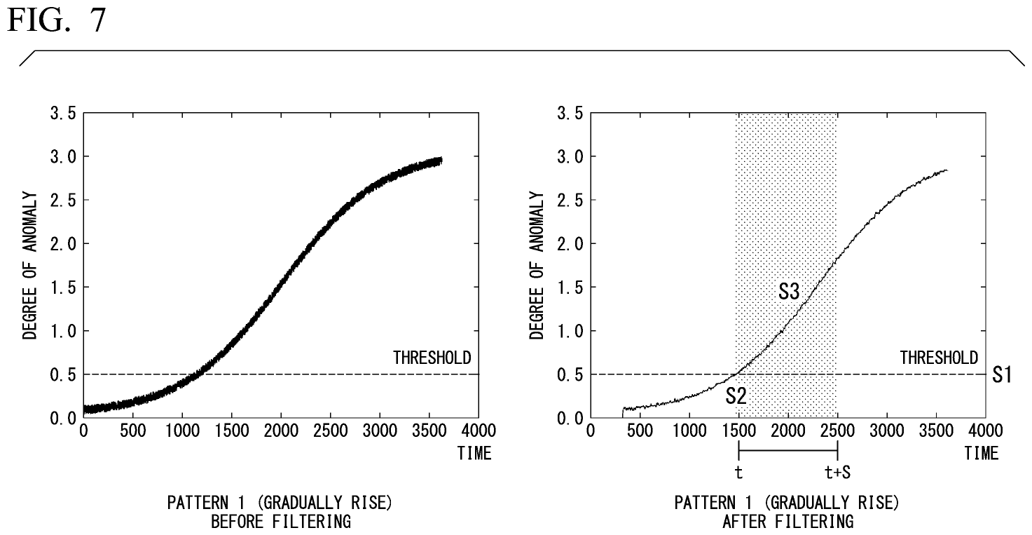

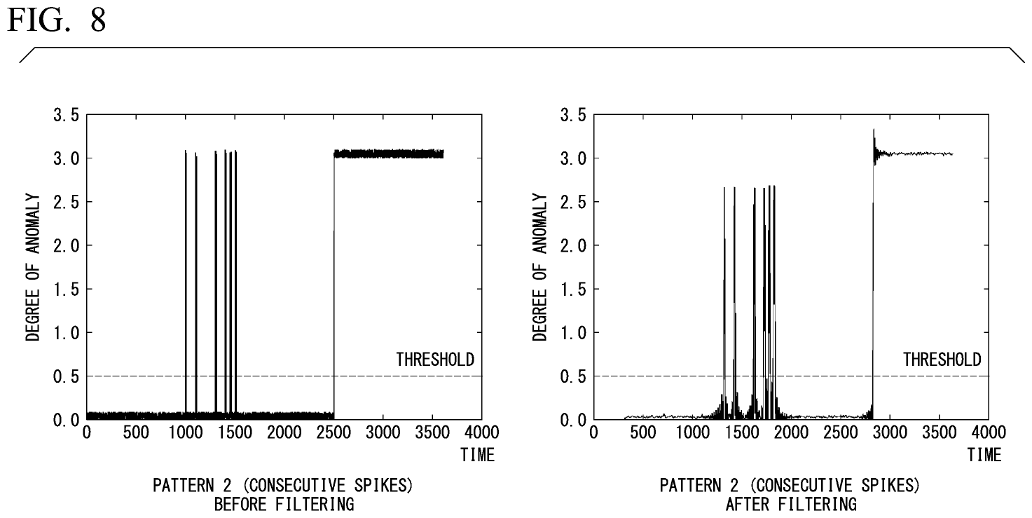

FIG. 7 shows the states of the time series data corresponding to Pattern 1 (gradual rise) shown in FIG. 2 before and after the filtering using the low-pass filter. FIG. 8 shows the states of the time series data corresponding to Pattern 2 (consecutive spikes) shown in FIG. 2 before and after the filtering using the low-pass filter.

In the example of FIG. 7, it has been ascertained that, as a result of reducing a sudden fluctuation of the degree of anomaly before the filtering, an uptrend in the degree of anomaly plotted in a smooth curve was easy to determine. In addition, a threshold of the filtered degree of anomaly was determined (S1), the time at which the degree of anomaly exceeded the threshold (the above-described activation time t) was recorded (S2), and it was checked whether the rise of the degree of anomaly was stable for the period from the activation time t to the time reached after a predetermined time S elapsed. In this example, it was ascertained that the rise of the degree of anomaly was not stable. Accordingly, it was ascertained that, in the subsequent process of the anomaly determiner 16, the gradual rise of the degree of anomaly was determined as an “anomaly.”

The example shown in FIG. 8 shows that, as a result of filtering, the consecutive spike-shaped degree of anomaly still exceeded the threshold although the magnitude of the degree of anomaly decreased overall. Accordingly, it was ascertained that, in the subsequent process of the anomaly determiner 16, the rise of the consecutive spike-shaped degree of anomaly was determined as an “anomaly.”

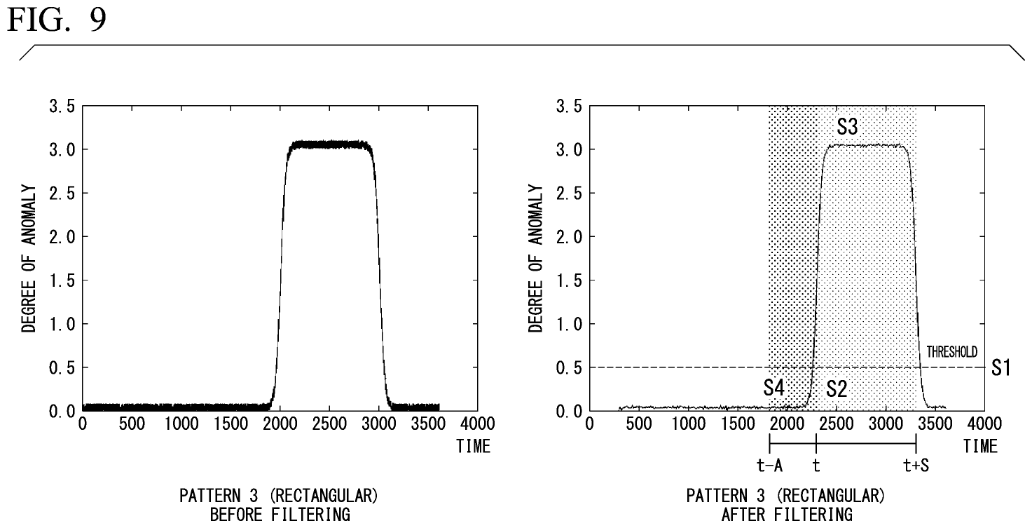

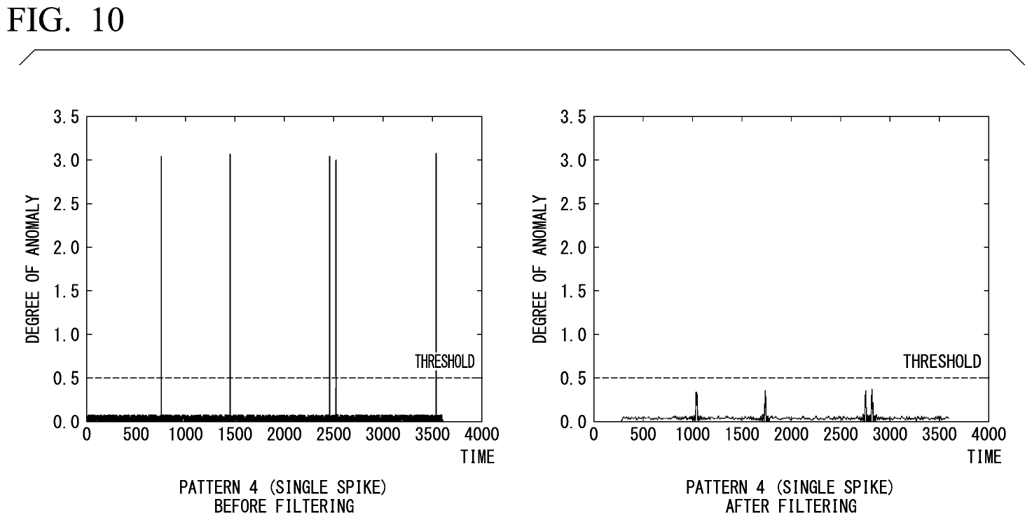

FIG. 9 shows the states before and after filtering was performed on time series data corresponding to Pattern 3 (a rectangle) shown in FIG. 2 using a low-pass filter in Example 1. FIG. 10 shows the states before and after filtering was performed on time series data corresponding to Pattern 4 (a single spike) shown in FIG. 2 using a low-pass filter in Example 1.

In the example shown in FIG. 9, it is ascertained that, as a result of reducing a sudden fluctuation in the degree of anomaly before the filtering, it became easy to determine the uptrend in the degree of anomaly with a smooth curve (a rectangular shape). In addition, a threshold for the filtered degree of anomaly was determined (S1), the time at which the degree of anomaly exceeded the threshold (the above-described activation time t) was recorded (S2), and it was checked whether the rise of the degree of anomaly was stable during the period from the activation time t to the time that reached after the predetermined time S elapsed. In this example, it was ascertained that the rise of the degree of anomaly was stable. In this case, by checking the status change history H during the period from a time t-A stored in the storage 24 to a time t (S4), it was possible to determine whether the sudden rise of the degree of anomaly was caused by a status change or was a sign of failure.

In addition, in the example shown in FIG. 10, the rise of the single spike-shaped degree of anomaly was reduced by filtering, and the degree of anomaly was thus reduced to below the threshold. Accordingly, it was ascertained that, in the subsequent process of the anomaly determiner 16, the rise of the single spike-shaped degree of anomaly was determined as “no anomaly” and it was possible to reduce false detection.

### Example 2

Next, in Example 2, time series data of a degree of anomaly was prepared, filtering was performed on the time series data of the degree of anomaly using a low-pass filter, and the state of the degree of anomaly when data determined to have a rectangular shape was learned was checked. The sampling frequency for the filtering was set to 1.0 (Hz), the number of taps was set to 600, and the cutoff frequency was set to 0.05 (Hz).

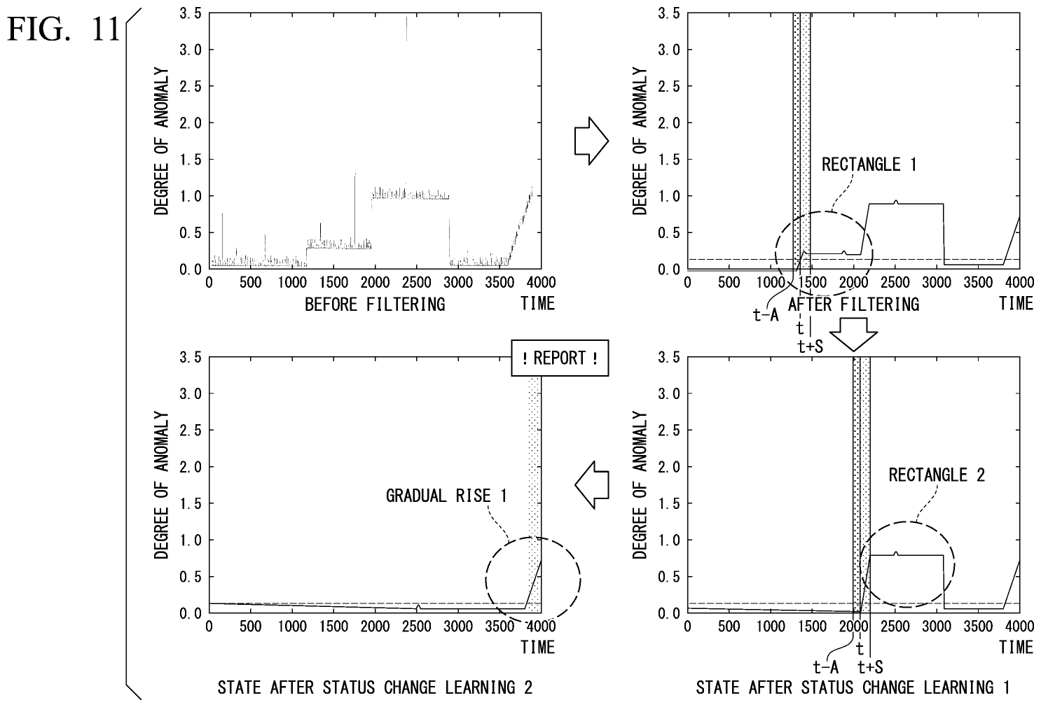

FIG. 11 shows the change of the degree of anomaly when filtering was performed on time series data of the degree of anomaly and the measurement values used for calculation of the degree of anomaly determined as being rectangular were learned. In this example, after filtering was performed on the time series data of the degree of anomaly using a low-pass filter, a measurement value after a status change in the range of a rectangle 1 was first learned and a new model was generated, and thereby a rise of the degree of anomaly in the range of the rectangle 1 was reduced (see the state after the learning of the status change 1). Further, a measurement value after a status change in the range of a rectangle 2 was learned and a new model was generated, and thereby a rise of the degree of anomaly in the range of the rectangle 2 was reduced (see the state after the learning of the status change 2). Accordingly, it was possible to detect an anomaly according to the rise of the degree of anomaly as indicated by the “gradual rise 1” in the state after the learning of the status change 2 and perform a reporting process.

According to the above-described embodiments, it is possible to reduce false detection in anomaly detection and to improve detection accuracy. Accordingly, a threshold for a degree of anomaly can be set to be low, and a sign of failure can be detected in an early stage. In addition, by updating a model when there is a status change, a measure for false detection can be automatically completed. Therefore, an operator does not need to correct models. In addition, even when learning of all status of the target device T has not been completed at the beginning of anomaly detection, anomaly detection can be normally executed and operated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An anomaly detection device comprising:
a calculator configured to calculate a degree of anomaly according to a predictive value that is predicted through machine learning using data acquired from a target device and a measurement value that is actually measured for the target device; and
a determiner configured to determine whether a change of the degree of anomaly indicates an anomaly of the target device according to a degree of a change of the degree of anomaly calculated by the calculator within a predetermined time range.

2. The anomaly detection device according to claim 1, further comprising:
a detector configured to detect the change of the degree of anomaly calculated by the calculator.

3. The anomaly detection device according to claim 2,
wherein the determiner is configured to refer to a status change history of the target device in a case in which the detector detects the change of the degree of anomaly in a direction of exceeding a threshold and a fluctuation of a value of the degree of anomaly falls within a predetermined range within a predetermined determination target time.

4. The anomaly detection device according to claim 3,
wherein, in a case in which there is a status change history of the target device before the degree of anomaly exceeds the threshold, the determiner is configured to determine that the change of the degree of anomaly does not indicate an anomaly of the target device.

5. The anomaly detection device according to claim 2,
wherein the detector is configured to perform filtering on the degree of anomaly and reduces the degree of anomaly of which a degree of a change with respect to time is equal to or higher than a predetermined value.

6. The anomaly detection device according to claim 1,
wherein the determiner is configured to determine whether data acquired from the target device is to be excluded from an evaluation target of a degree of anomaly in accordance with a preset determination condition of a degree of anomaly.

7. The anomaly detection device according to claim 1, further comprising:
a learner configured to generate learning data in which data acquired after a change of a status of the target device and data used for generating a first model used in the machine learning are mixed and to generate a second model using the learning data in a case in which the determiner determines that there is a status change history of the target device and the change of the degree of anomaly does not indicate an anomaly of the target device before the degree of anomaly exceeds a threshold.

8. The anomaly detection device according to claim 7, further comprising:
a decider configured to compare accuracies of the first model used in the machine learning and the second model generated by the learner and to decide a model with higher accuracy as a model to be used for machine learning.

9. The anomaly detection device according to claim 8,
wherein the decider is configured to compare a first degree of anomaly calculated according to the first model and a second degree of anomaly calculated according to a second model and to decide the model with the lower absolute value of the calculated degree of anomaly as a model to be used for machine learning.

10. The anomaly detection device according to claim 1, further comprising:
a reporter configured to report occurrence of an anomaly in a case in which the determiner determines that the change of the degree of anomaly indicates an anomaly of the target device.

11. An anomaly detection method comprising:
calculating a degree of anomaly according to a predictive value that is predicted through machine learning using data acquired from a target device and a measurement value that is actually measured for the target device; and
determining whether a change of the degree of anomaly indicates an anomaly of the target device according to a degree of a change of the calculated degree of anomaly within a predetermined time range.

12. A non-transitory computer-readable storage medium storing program causing a computer to perform:
calculating a degree of anomaly according to a predictive value that is predicted through machine learning using data acquired from a target device and a measurement value that is actually measured for the target device; and
determining whether a change of the degree of anomaly indicates an anomaly of the target device according to a degree of a change of the calculated degree of anomaly within a predetermined time range.
